(19) United States
(12) Patent Application Publication
(10) Pub. No.: US 2015/0179877 A1
(43) Pub. Date: Jun. 25, 2015

(54) NANOWIRE DEVICE

(71) Applicant: LuxVue Technology Corporation, Santa Clara, CA (US)

(72) Inventors: Hsin-Hua Hu, Los Altos, CA (US); Kelly McGroddy, San Francisco, CA (US); Andreas Bibl, Los Altos, CA (US)

(73) Assignee: LuxVue Technology Corporation, Santa Clara, CA (US)

(21) Appl. No.: 14/137,856

(22) Filed: Dec. 20, 2013

(51) Int. Cl. H01L 33/06; H01L 33/42; H01L 33/40

(52) U.S. Cl. CPC H01L 33/06; H01L 33/405; H01L 33/42

(57) ABSTRACT

A nanowire device and a method of forming a nanowire device that is poised for pick up and transfer to a receiving substrate are described. In an embodiment, the nanowire device includes a base layer and a nanowire on and protruding away from a first surface of the base layer. The nanowire may include a core, a shell, and an active layer between the core and the shell. A top electrode layer may be on a second surface of the base layer opposite the first surface and in electrical contact with the core, and a bottom electrode layer may be on and electrical contact with the shell. In an embodiment, the base layer is characterized by a maximum width of the micro scale, and the nanowire is characterized by a maximum width or length of the nano scale.

### BACKGROUND

1. Field

The present invention relates to nanowire devices. More particularly embodiments of the present invention relate to nanowire LED devices.

2. Background Information

Light emitting diodes (LEDs) are increasingly being considered as a replacement technology for existing light sources. For example, LEDs are found in signage, traffic signals, automotive tail lights, mobile electronics displays, and televisions. Various benefits of LEDs compared to traditional lighting sources may include increased efficiency, longer lifespan, variable emission spectra, and the ability to be integrated with various form factors.

Conventional planar-type semiconductor-based LEDs are generally patterned from layers grown across a wafer surface. More particularly, planar-type semiconductor-based LEDs include one or more semiconductor-based active layers sandwiched between thicker semiconductor-based cladding layers. More recently bottom-up approaches have been used to form nanowire LED structures that may offer several advantages to the planar-type LEDs, including lower dislocation density, greater light extraction efficiency, and a larger active region surface area relative to substrate surface area.

In one implementation illustrated in FIG. 1 a bulk LED substrate 100 includes a buffer layer 110 grown on a growth substrate 102. A patterned mask layer 112 (e.g. a nitride layer, such as silicon nitride masking layer) is then formed on a surface of the buffer layer 110 to define the bottom interface area for growth of the nanowire cores 114 using a suitable growth technique such as chemical beam epitaxy or vapor phase epitaxy. Thus, the bottom-up formation of each nanowire core 114 may be accomplished using the crystallographic orientation of the underlying buffer layer 110 without the required use of a particle or catalyst, and the width and pitch of the nanowire cores 116 can be defined by lithographic patterning of mask layer 112.

Epitaxial growth conditions for the nanowire cores may be controlled for vertical growth direction. Once the determined height is achieved, epitaxial growth conditions are changed to create a core-shell structure with the active layer 116 and doped shell 118 around the nanowire cores 114. Alternatively, nanowires can be formed using a similar technique using vertical growth conditions for the active layer and both cladding layers resulting in a sandwiched configuration similar to the planar-type LEDs rather than a core-shell structure.

Devices implementing arrays of nanowires are typically packaged in two manners. One includes leaving the array of nanowires on the original growth substrate such as described in U.S. Pat. No. 7,396,696 and U.S Publication No. 2011/0240959. In such implementations, the buffer layer functions as an electric current transporter layer to which a bottom electrode is formed, and a common top electrode is formed over the array of nanowires. Another implementation includes flip chip packaging the arrays of nanowires onto a receiving substrate using solder bumps then removing the growth substrate as described in U.S Publication Nos. 2011/0309382 and 2011/0254034.

### SUMMARY OF THE INVENTION

Nanowire devices and methods of forming nanowire devices that are poised for pick up and transfer to a receiving substrate are described. In an embodiment a nanowire device includes a base layer and a nanowire on and protruding away from a first surface of the base layer. The nanowire includes a core, a shell, and an active layer between the core and the shell. A top electrode layer is on a second surface of the base layer opposite the first surface and in electrical contact with the core. A bottom electrode layer is on and in electrical contact with the shell. The top electrode layer may be formed of a transparent or semi-transparent material. In an embodiment, the top electrode layer covers substantially all the second surface of the base layer. The bottom electrode layer may include a layer stack. For example, the bottom electrode layer can include layers such as a mirror layer and/or a bonding layer formed of a noble metal. In another embodiment, the bottom electrode layer is formed of a transparent or semi-transparent material while the top electrode layer includes a mirror layer.

In some embodiments the nanowire device includes a plurality of nanowires on and protruding away from the first surface of the base layer, with each nanowire comprising a core, shell and active layer between the core and the shell. The top electrode layer is on the second surface of the base layer opposite the first surface and in electrical contact with the core of each nanowire. One or more bottom electrode layers are on and in electrical contact with the shells of the plurality of nanowires. In an embodiment, a plurality of bottom electrode layers is on and in electrical contact with the shells of the plurality of nanowires. In an embodiment, a patterned mask layer is one the base layer, were the cores of the plurality of nanowires extend through corresponding openings in the patterned mask layer. A through-hole may also be formed through an entire thickness of the base layer and the mask layer laterally between two nanowires.

In accordance with some embodiments, an array of nanowire devices is poised for pick up and transfer to a receiving substrate. Such a structure may include a stabilization layer on a carrier substrate. An array of staging cavities is formed in the stabilization layer, and an array of nanowire devices is within the array of staging cavities. In such an embodiment, each nanowire may include a base layer characterized by a maximum width of the micro scale, and a nanowire on and protruding away from the base layer, the nanowire characterized by a maximum width of the nano scale. A sacrificial release layer may span between the stabilization layer and the array of nanowire devices. For example, the nanowire devices may be embedded in the sacrificial release layer. The sacrificial release layer may span along a bottom-most location of the bottom electrode layer for each nanowire. Alternatively, the sacrificial release layer may include an array of openings such that the sacrificial release layer does not span along a bottom-most location of the bottom electrode layer for each nanowire. In such a configuration, the bottom electrode layer for each nanowire may be in direct contact with the stabilization layer. In an embodiment, the stabilization layer is formed of a thermoset material.

In an embodiment, an array of nanowire devices is picked up from a carrier substrate with an electrostatic transfer head assembly supporting an array of electrostatic transfer heads. A receiving substrate is contacted with the array of nanowire devices. The array of nanowire devices is bonded to the receiving substrate and released onto the receiving substrate. Picking up the array of nanowire devices from the carrier substrate may include contacting the top electrode layer of each nanowire device with a corresponding electrostatic transfer head. In accordance with embodiments of the invention, a sacrificial release layer is removed from between the array of nanowire devices and the carrier substrate prior to picking up the array of nanowire devices.

In an embodiment, formation of nanostructures such as nanowire devices includes depositing a bottom electrode layer on a nanowire, where the nanowire protrudes from a base layer formed on a handle substrate, and the nanowire includes a core, a shell, and an active layer between the core and the shell. A mesa trench is etched through the base layer so that the mesa trench laterally surrounds the nanowire. A sacrificial release layer is deposited over the base layer and the nanowire, and within the mesa trench. The handle substrate is then bonded to a carrier substrate with a stabilization layer so that the nanowire is retained within the stabilization layer. The handle substrate is then removed. In an embodiment, bonding the handle substrate to the carrier substrate with the stabilization layer includes coating a thermosetting material over the sacrificial layer and cured. In an embodiment, bonding the handle substrate to the carrier substrate with the stabilization layer includes coating a foundation layer over the sacrificial release layer, reducing a thickness of the foundation layer, removing a portion of the sacrificial release layer to expose a portion of the bottom electrode layer over the nanowire, and coating a cap layer over the foundation layer.

### BRIEF DESCRIPTION OF THE DRAWINGS

FIG. 1 is a cross-sectional side view illustration of a bulk LED substrate including an array of nanowires formed over a buffer layer.

FIG. 2A is a cross-sectional side view illustration of an array of bottom electrodes formed over a bulk LED substrate including an array of nanowires in accordance with an embodiment of the invention.

FIG. 2B is a cross-sectional side view illustration of a bulk LED substrate including an array of nanowires formed on a handle substrate including a buffer layer in accordance with an embodiment of the invention.

FIG. 2C is a cross-sectional side view illustration of an array of bottom electrodes formed over a bulk LED substrate including an array of nanowires in accordance with an embodiment of the invention.

FIG. 3A is a cross-sectional side view illustration of an array of mesa trenches formed around an array of nanowires in accordance with an embodiment of the invention.

FIG. 3B is a cross-sectional side view illustration of an array of mesa trenches and through holes formed through a base layer in accordance with an embodiment of the invention.

FIG. 3C is a cross-sectional side view illustration of an array of mesa trenches and through holes formed partially through a base layer in accordance with an embodiment of the invention.

FIG. 4 is a cross-sectional side view illustration of a sacrificial release layer formed over the array of nanowires and array of bottom electrodes, and within the array of mesa trenches in accordance with an embodiment of the invention.

FIG. 5 is a cross-sectional side view illustration of a handle substrate bonded to a carrier substrate with a stabilization layer in accordance with an embodiment of the invention.

FIG. 6 is a cross-sectional side view illustration of an array of nanowire mesa structures after removal of a handle substrate in accordance with an embodiment of the invention.

FIG. 7 is a cross-sectional side view illustration of a top electrode layer formed over an array of nanowire mesa structures in accordance with an embodiment of the invention.

FIG. 8 is a cross-sectional side view illustration of a patterning layer formed over a top electrode layer formed over an array of nanowire mesa structures in accordance with an embodiment of the invention.

FIG. 9 is a cross-sectional side view illustration of an array of nanowire devices retained in a stabilization layer after partial removal of a top electrode layer in accordance with an embodiment of the invention.

FIG. 10 is a cross-sectional side view illustration of an array of nanowire devices within an array of staging cavities in a stabilization layer after removal of a sacrificial release layer in accordance with an embodiment of the invention.

FIGS. 11A-11B are cross-sectional side view illustrations of an array of bottom electrode layers in direct contact with a stabilization layer in accordance with an embodiments of the invention.

FIG. 12 is a cross-sectional side view illustration of a cap layer coated over the foundation layer and bonded to a receiving substrate.

FIG. 13 is a cross-sectional side view illustration of an array of nanowire mesa structures after removal of a handle substrate in accordance with an embodiment of the invention.

FIG. 14 is a cross-sectional side view illustration of an array of nanowire devices within an array of staging cavities in a stabilization layer after removal of a sacrificial release layer in accordance with an embodiment of the invention.

FIG. 15 is a schematic top view illustration of base layer patterned to form an array of through holes and mesa trenches surrounding arrays of nanowires in accordance with an embodiment of the invention.

FIG. 16A-16E are cross-sectional side view illustrations of an array of electrostatic transfer heads transferring nanowire devices from a carrier substrate to a receiving substrate in accordance with an embodiment of the invention.

FIG. 17 is a schematic illustration of a display system in accordance with an embodiment of the invention.

FIG. 18 is a schematic illustration of a lighting system in accordance with an embodiment of the invention.

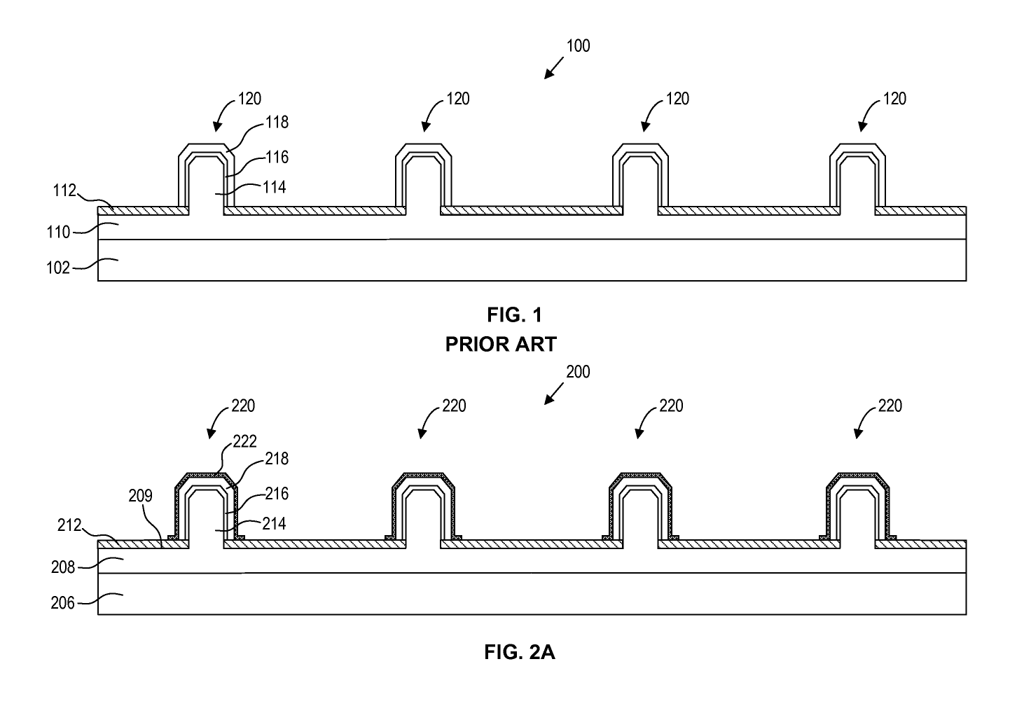

### DETAILED DESCRIPTION OF THE INVENTION

Embodiments of the present invention describe nanowire devices. For example, an array of nanowires may be grown on a base layer and bonded to a carrier substrate with a stabilization layer where the bonded structure is further processed to form an array of nanowire devices that is poised for pick up and transfer to a receiving substrate. While some embodiments of the present invention are described with specific regard to nanowire LED devices, it is to be appreciated that embodiments of the invention are not so limited and that certain embodiments may also be applicable to other nanowire based semiconductor devices such as field effect transistors (FETs), diodes, solar cells, and detectors where a base layer is used as a seed for growing the nanowires or may serve as an electric current transporter layer.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the present invention. In other instances, well-known semiconductor processes and manufacturing techniques have not been described in particular detail in order to not unnecessarily obscure the present invention. Reference throughout this specification to “one embodiment” means that a particular feature, structure, configuration, or characteristic described in connection with the embodiment is included in at least one embodiment of the invention. Thus, the appearances of the phrase “in one embodiment” in various places throughout this specification are not necessarily referring to the same embodiment of the invention. Furthermore, the particular features, structures, configurations, or characteristics may be combined in any suitable manner in one or more embodiments.

The terms “spanning”, “over”, “to”, “between” and “on” as used herein may refer to a relative position of one layer with respect to other layers. One layer “spanning,” “over” or “on” another layer or bonded “to” or in “contact” with another layer may be directly in contact with the other layer or may have one or more intervening layers. One layer “between” layers may be directly in contact with the layers or may have one or more intervening layers.

In one aspect, embodiments of the invention describe nanowire devices including a nanowire protruding away from a base layer. For example, the nanowire may comprise a core-shell configuration. Since the active area of the nanowire is determined by the length of the wire, which is orthogonal to the surface of the base layer from which it protrudes, the amount of active area can be increased relative to the available horizontal area of the base layer, particularly when a plurality of nanowires protrude away from the base layer. Furthermore, nanowire device configurations in accordance with embodiments of the invention can be used to achieve specific effective current densities through the nanowire devices, with the effective current density being proportional to the number of nanowires protruding from the base layer, and LED junction (e.g. quantum well) surface area for the nanowires. For example, highest effective current densities may be achieved with a single nanowire protruding from the base layer. Effective current densities can be reduced by increasing the number of nanowires in a nanowire device. In accordance with embodiments of the invention, the number of nanowires in a nanowire device can be adjusted to achieve a desired effective current density that correlates to a specific efficiency of the device, particularly at low operating currents (e.g. scale of milli-amperes and lower) and effective current densities (e.g. scale of amperes per square centimeter and lower) for the nanowire devices below a characteristic “efficiency droop” where a gradual increase in effective current density may result in a significant increase in efficiency of the nanowire device.

In another aspect, embodiments of the invention describe a nanowire device integration design in which a nanowire device is transferred from a carrier substrate and bonded to a receiving substrate using an electrostatic transfer head assembly. In accordance with embodiments of the present invention, a pull-in voltage is applied to an electrostatic transfer head in order to generate a grip pressure on a nanowire device and pick up the nanowire device. It has been observed that it can be difficult to impossible to generate sufficient grip pressure to pick up devices with vacuum chucking equipment when device sizes are reduced below a specific critical dimension of the vacuum chucking equipment, such as approximately 300 μm or less, or more specifically approximately 100 μm or less. Furthermore, electrostatic transfer heads in accordance with embodiments of the invention can be used to create grip pressures much larger than the 1 atm of pressure associated with vacuum chucking equipment. For example, grip pressures of 2 atm or greater, or even 20 atm or greater may be used in accordance with embodiments of the invention. Accordingly, in one aspect, embodiments of the invention provide the ability to transfer and integrate nanowires into applications in which integration was previously not possible by using an electrostatic transfer head assembly to transfer and integrate nanowires devices that include nanowires fabricated on the nano-scale that protrude from a base layer fabricated with a larger dimension, such as on the micro-scale. In accordance with embodiments of the invention a top surface of the base layer opposite a bottom surface of the base layer from which the nanowire protrudes can be used as a contact area for an electrostatic transfer head of an electrostatic transfer head assembly to contact the nanowire device. For example, each electrostatic transfer head may be fabricated at a similar scale as the top surface of the base layer for a corresponding nanowires device.

In some embodiments, the term “micro” structure or scale as used herein may refer to the descriptive size, e.g. width, of certain devices or structures. In some embodiments, “micro” structure or scale may be on the scale of 1 μm to approximately 300 μm, or 100 μm or less in many applications. For example, a base layer of a nanowire device or electrostatic transfer head may have a contact surface characterized by a maximum dimension (e.g. width) at the micro scale. However, it is to be appreciated that embodiments of the present invention are not necessarily so limited, and that certain aspects of the embodiments may be applicable to larger micro structure or scale, and possibly smaller size scales. In some embodiments, the term “nano” structure or scale as used herein may refer to the descriptive size, e.g. length or width, of certain devices or structures. In some embodiments, “nano” structure or scale may be on the scale of less than 1 μm. For example, a maximum width of a nanowire may be of the nano scale. However, it is to be appreciated that embodiments of the present invention are not necessarily so limited, and that certain aspects of the embodiments may be applicable to larger nano structure or scale.

In another aspect, embodiments of the invention describe a structure for stabilizing an array of nanowires devices on a carrier substrate so that they are poised for pick up and transfer to a receiving substrate. In an embodiment, an array of nanowire devices are held within a corresponding array of staging cavities in which each nanowire device is laterally surrounded by sidewalls of a corresponding staging cavity. Due to the complex topographic profile of the nanowires protruding away from the base layer, and manner of forming the stabilization layer, each staging cavity may conform to the profile of the protruding nanowires resulting in a key-hole structure where a prong-like profile of the nanowires extend into similarly shaped openings of the stabilization structure. In this manner, the array of nanowires devices may be stabilized within staging cavities in a stabilization layer. In accordance with embodiments of the invention, each nanowire device may be embedded within a sacrificial release layer within the array of staging cavities. When the array of nanowires devices are embedded within the sacrificial release layer the structure may be durable for handling and cleaning operations to prepare the structure for subsequent sacrificial release layer removal and electrostatic pick up.

In some embodiments, upon removal of the sacrificial release layer the array of nanowire devices may drop into the staging cavities due to removal of the sacrificial release layer below the array of nanowires devices. This may significantly reduce the adhesion of the array of micro devices in the stabilization structure. In accordance with embodiments of the invention, adhesion between the staging cavity and the nanowire device after removal of the sacrificial release layer is less than adhesion between the nanowires device and the sacrificial release layer. In an embodiment, covalent bonds between a deposited sacrificial release layer and nanowire device may be removed, for example, covalent bonds associated with chemical vapor deposition (CVD). Accordingly, removal of the sacrificial release layer may remove adhesive forces resulting from layer on layer deposition. Furthermore, the nanowire devices are laterally restrained within the array of staging cavities after removal of the sacrificial release layer. In this manner, the array of nanowires devices is poised for pick up with lower required pick up pressure, and the array of staging cavities ensures proper spacing of the array of nanowire devices for pick up.

In some embodiments, the array of nanowires devices is in direct contact with and is supported by the stabilization layer, and the array of nanowires devices does not drop into the staging cavities upon removal of the sacrificial release layer. In accordance with embodiments of the invention, the minimum amount pick up pressure required to pick up a nanowire device from a stabilization layer can be determined by the adhesion strength between an adhesive bonding material from which the stabilization layer is formed and the nanowire device. In some embodiments this may be determined by the contact area between the bottom electrode on each nanowire and the stabilization layer. For example, adhesion strength which must be overcome to pick up a nanowire device is related to the minimum pick up pressure generated by a transfer head as provided in equation (1):

P₁A₁=P₂A₂ (1)

where P₁ is the minimum grip pressure required to be generated by a transfer head, A₁ is the contact area between a transfer head contact surface and nanowire device contact surface, A₂ is the contact area between the bottom electrode for a nanowire and the stabilization layer, and P₂ is the adhesion strength of the stabilization layer to the bottom electrode. In an embodiment, a grip pressure of greater than 1 atmosphere is generated by a transfer head. For example, each transfer head may generate a grip pressure of 2 atmospheres or greater, or even 20 atmospheres or greater without shorting due to dielectric breakdown of the transfer heads. In some embodiments, due to the smaller area, a higher pressure is realized at the contact area between the bottom electrode on each nanowire and the stabilization layer than the grip pressure generate by a transfer head. In accordance with some embodiments of the invention, the adhesion between the nanowires devices and the stabilization layer is controlled by the contact area of the bottom electrode with the stabilization layer, as well as materials selection for bonding the bottom electrode to the stabilization layer.

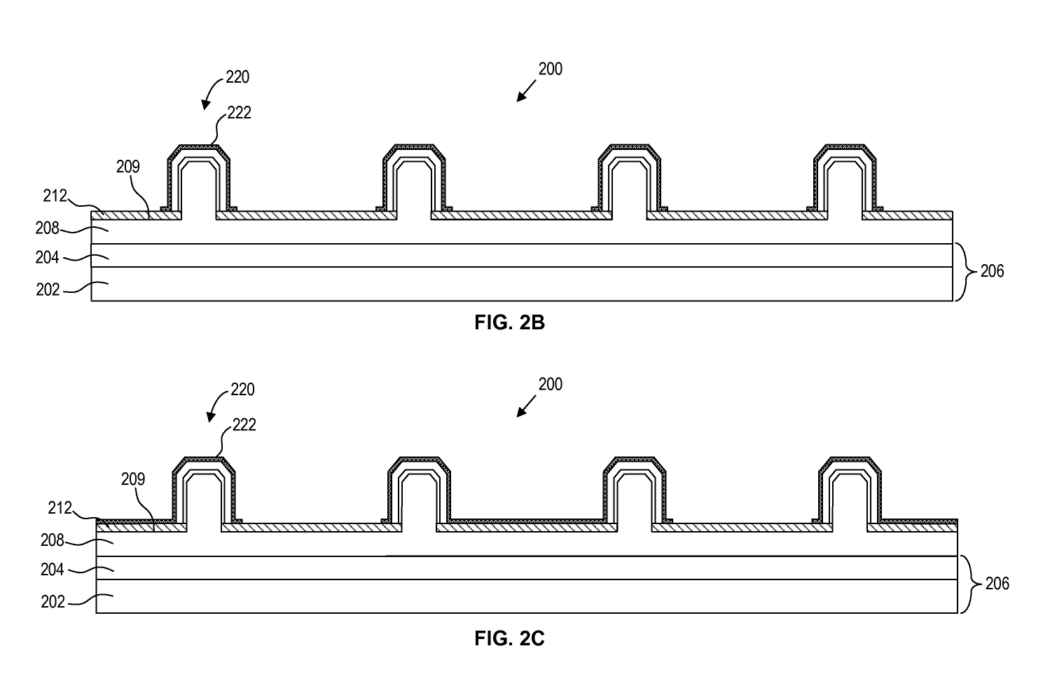

FIG. 2A is a cross-sectional side view illustration of an array of bottom electrodes formed over a bulk LED substrate including an array of nanowires in accordance with an embodiment of the invention. As shown the bulk LED substrate 200 may include a handle substrate 206, a base layer 208 grown upon the handle substrate 206, and an array of nanowires 220 formed on and protruding away from surface 209 of the base layer 208 and through an array of openings formed in a masking layer 212 formed on the surface 209. Each nanowire 220 includes a core 214, a shell 218, and an active layer 216 between the core and the shell. In an embodiment, the masking layer 212 may be formed of a nitride (e.g. SiNₓ) material, and patterned using lithographic techniques to form openings through which each core 214 protrudes. The core and shell may have opposite doping. For example, an n-doped core 214 may be surrounded by a p-doped shell 218, or a p-doped core may be surrounded by an n-doped shell. Active layer 216 may include one or more layers, for example, one or more quantum well layers separated by barrier layers. As illustrated in FIG. 2A, an electrode 222 is formed on the shell 218. In an embodiment, the electrode 222 may form a shell around shell 218. For example, the electrode 222 may be formed adjacent portions of shell 218 that are adjacent the active layer 216. This may increase emission uniformity along surfaces of the nanowires 220. As will become apparent in the following processing sequences, the electrode 222 will become the bottom electrode for a nanowire device.

Each nanowire 220 may be formed of a variety of compound semiconductors having a bandgap corresponding to a specific region in the spectrum. For example, the nanowires illustrated in FIG. 2A may be designed for emission of red light (e.g. 620-750 nm wavelength), green light (e.g. 495-570 nm wavelength), blue light (e.g. 450-495 nm wavelength), or other wavelengths such as yellow, orange, or infra-red. In the following description exemplary processing sequences are described for forming an array of nanowire LED devices with core-shell configurations based upon GaN materials. While the primary processing sequences are described for specific materials, it is to be understood that the exemplary processing sequences can be used for fabricating nanowires with different emission spectra, and that certain modifications are contemplated, particularly when processing different materials. For example, it is contemplated that the core 214 and shell 218 can include one or more layers based on II-VI materials (e.g. ZnSe) or III-V materials including III-V nitride materials (e.g. GaN, AlN, InN, InGaN, and their alloys) and III-V phosphide materials (e.g. GaP, AlGaInP, and their alloys). The handle substrate 206 may include a growth substrate formed of any suitable material such as, but not limited to, silicon, SiC, GaAs, GaN, and sapphire.

Referring to FIG. 2B, in an embodiment, the bulk LED substrate 200 includes a handle substrate 206 that includes a growth substrate 202 formed of sapphire, and may be approximately 200 μm thick. A buffer layer 204 formed of GaN is grown upon the growth substrate 202 to a thickness of approximately 0.5 μm to 5 μm. Following the formation of the buffer layer 204, a base layer 208 is grown upon the buffer layer 204. In an embodiment, the base layer 208 is doped similarly as the core 214 to reduce defects during growth of the core 214, as well as to provide an electrical connection. For example, the base layer 208 and core 214 may be a n-doped GaN material. In an embodiment, the base layer 208 is approximately 1 μm thick, and the core 214 is approximately 1 μm-5 μm tall and has a width of up to 1 μm, such as 0.2 μm-1 μm. In an embodiment, core 214 is selectively grown in a vertical direction along c-plane growth of the underlying GaN base layer 208.

In an embodiment, a pitch from center to center between adjacent cores 106 is sufficient to allocate enough space to perform lithographic patterning techniques such as a photoresist lift-off technique for forming the bottom electrodes 222. In an embodiment, the pitch is approximately 1 μm or more, for example, approximately 2.5 μm. Following the formation of core 214, growth conditions are modified to accomplish lateral growth, such as m-plane growth, in addition to continuing vertical growth to form active layer 216 and shell layer 218. Active layer 216 may include one or more quantum well and barrier layers. Shell layer 218 may have the opposite doping than core 214. For example, where core 214 is n-doped, the shell layer 218 is p-doped. In an embodiment, shell layer 218 has a thickness of 0.1 μm-0.5 μm. In an embodiment, both are formed of GaN. In an embodiment, each nanowire 220 may conform to a hexagonal configuration when viewed from above, corresponding to m-plane growth.

Referring to all of FIGS. 2A-2C, a variety of configurations are possible for the electrode 222. In an embodiment, a separate electrode 222 is formed over each nanowire 220. In such an embodiment, the electrode 222 may also be partially formed on the masking layer 212 and only partially span between adjacent nanowires 220. In an embodiment illustrated in FIG. 2C, a plurality of nanowires 220 may share a single electrode 222. In such an embodiment, the electrode 222 may also be formed on the masking layer 212 and completely span between adjacent nanowires 220.

Electrodes 222 may be formed using a variety of deposition methods, such as evaporation or sputtering. Patterning of electrodes 222 may be formed by blanket deposition followed by lithography and etching, or the electrodes 222 may be formed using a photoresist lift-off technique. In an embodiment, a center-to-center spacing between adjacent nanowires 220 is maintained in order to allow sufficient room for patterning the photoresist for a photoresist lift-off technique.

Electrode 222 may be formed of a variety of conductive materials including metals, conductive oxides, and conductive polymers. The bottom electrode 222 may be formed of a single layer, or a layer stack. Electrode 222 may be transparent or semi-transparent. Electrode 222 may include a mirror layer that is reflective to the visible wavelength emitted by the nanowire 220. Electrode 222 may include a combination of transparent or semi-transparent materials with a mirror layer.

In an embodiment, bottom electrode 222 is formed of a transparent conductive oxide such as ITO. In an embodiment, bottom electrode 222 is formed of a metallic material such as palladium, or NiAu. In an embodiment, the bottom electrode 222 includes a mirror layer to reflect the emitted wavelength from the nanowire. For example, a gold, aluminum, or silver mirror layer may be suitable for reflecting the red wavelength spectrum, while a silver or aluminum mirror layer may be suitable for reflecting the blue or green wavelength spectrum. In an embodiment, the bottom electrode includes a bonding layer to control adhesion strength with the stabilization layer. For example, a noble metal such as gold may be used where the stabilization layer is formed of benzocyclobutene (BCB). In an embodiment, the bottom electrode includes other layers such as layers for ohmic contact and barrier layers. A number of configurations are possible. Accordingly, the bottom electrode may be a single layer or a layer stack in accordance with embodiments of the invention.

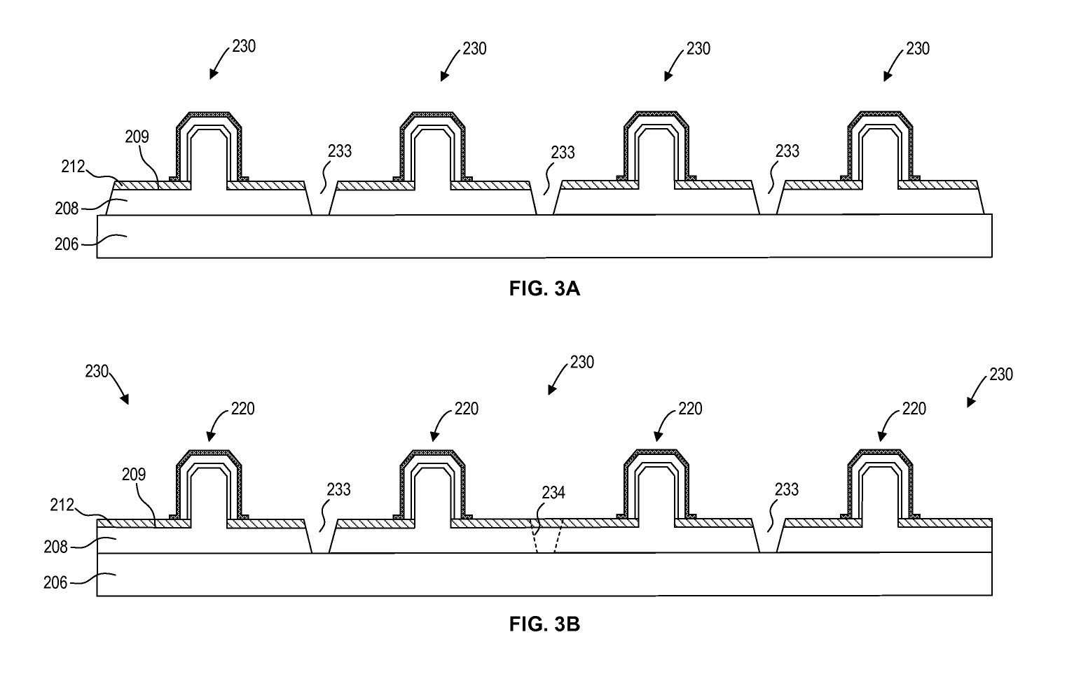

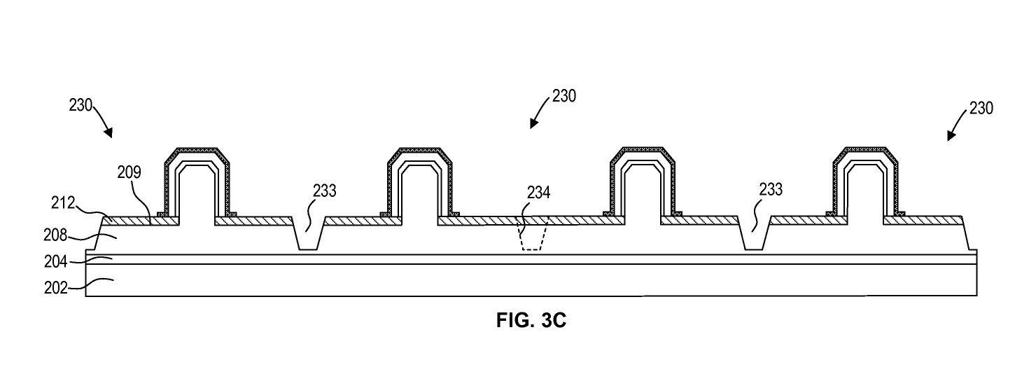

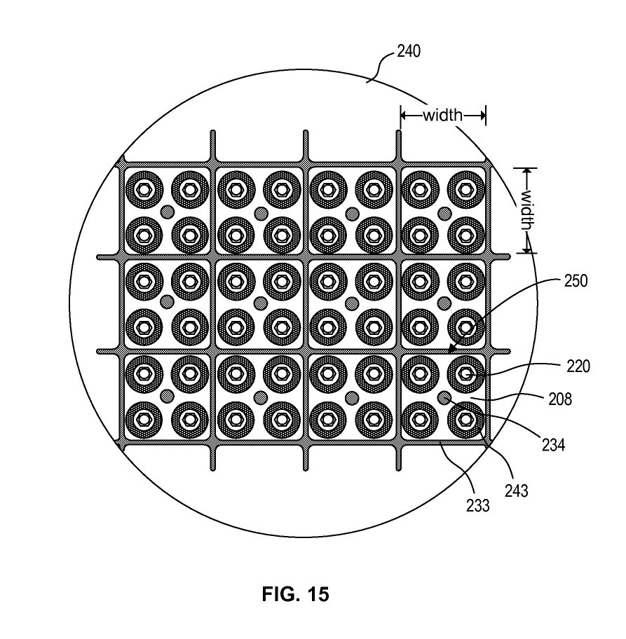

Referring now to FIGS. 3A-3B, the masking layer 212 and base layer 208 are patterned to form an array of mesa structures 230 separated by an array of mesa trenches 233 over the handle substrate 206. As illustrated in FIG. 3B, in applications in which a plurality of nanowires 220 are connected to a mesa structure 230, one or more through holes 234 may also be formed through the masking layer 212 and base layer 208 to aid with subsequent removal of a sacrificial release layer. Referring briefly to the top schematic view illustration in FIG. 15, in accordance with embodiments of the invention, the mesa trenches 233 may laterally surround the base layer 208 and one or more nanowires 220 for each mesa structure 230, while the one or more through holes 234 may be located laterally between adjacent nanowires 220 protruding from surface 209 of base layer 208.

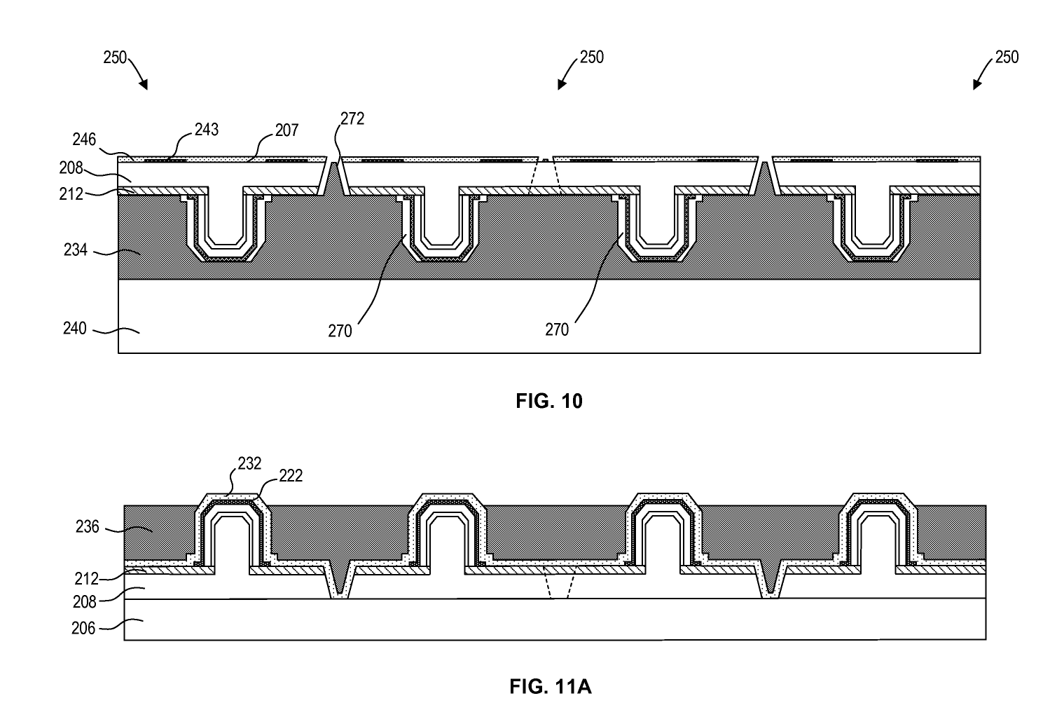

In accordance with embodiments of the invention, the base layer 208 for each mesa structure 230, and corresponding nanowire device 250 to be formed may be formed on the micro scale. For example, referring to the nanowire devices illustrated in FIGS. 10 and 14, each base layer 208 may have a top surface 207 characterized by a maximum length or width of 300 μm or less, or more particularly 100 μm or less. In an embodiment, each base layer 208 has a top surface 207 characterized by a maximum length or width of 1 to 20 μm.

In an embodiment illustrated in FIG. 3C, mesa trenches 233 and optional through holes 234 extend partially into the base layer 208 in each of the mesa structures 230. For example, in an embodiment mesa trenches 233 and optional through holes 234 extend partially into an n-doped GaN base layer 208, but do not extend into an underlying GaN buffer layer 204. In another exemplary embodiment, mesa trenches 233 and optional through holes 234 extend completely through an n-doped GaN base layer 208 and partially or completely through an underlying GaN buffer layer 204.

Etching of the mesa trenches 233 and optional through holes 234 may be performed sequentially, in either order, or simultaneously. In an embodiment, 233, 234 are simultaneously etched. Etching may be wet or dry depending upon the desired angles for sidewalls of the mesa trenches 233 and optional through holes 234. If a continuous bottom electrode layer 222 is formed over the array of nanowires 220 the bottom electrode layer 222 may also be etched during etching of the mesa trenches 233 and optional through holes 234 using the same or different etching chemistry. In an embodiment, dry etching techniques such as reactive ion etching (RIE), electro-cyclotron resonance (ECR), inductively coupled plasma reactive ion etching (ICP-RIE), and chemically assisted ion-beam etching (CAME) may be used. The etching chemistries for FIGS. 3A-3C may be halogen based, containing species such as Cl₂, BCl₃, or SiCl₄.

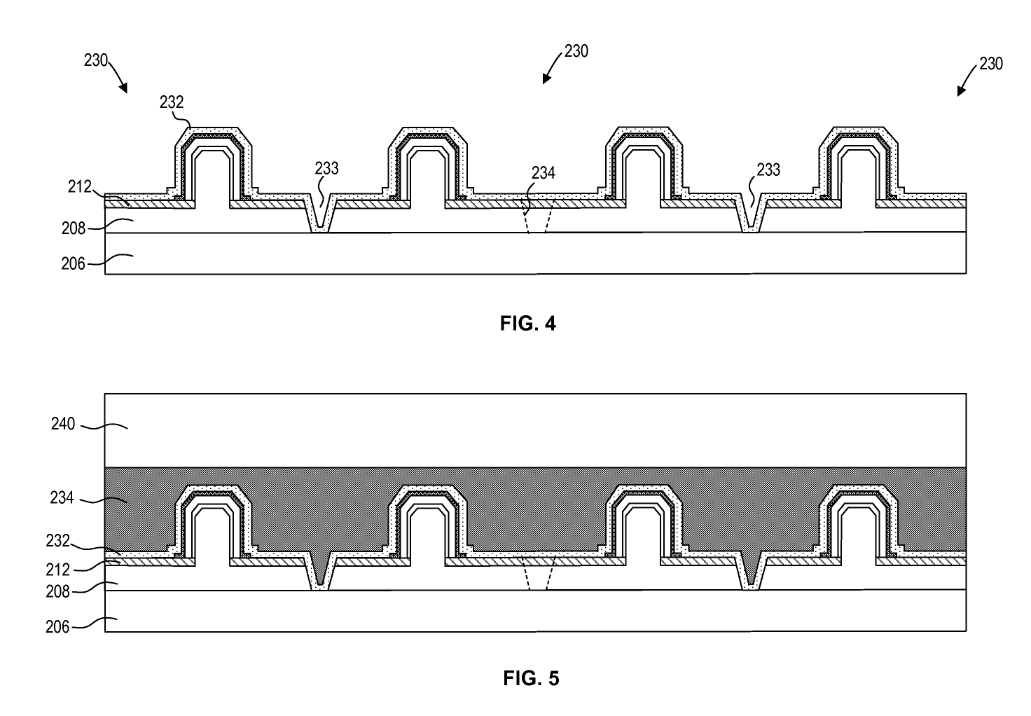

A sacrificial release layer 232 may then be formed over the array of mesa structures 230 as illustrated in FIG. 4 so that the nanowires 220 and base layers 208 are embedded within the sacrificial release layer 232. In the particular embodiment illustrated, the sacrificial release layer 232 is formed within the mesa trenches 116 as well as within the through holes 234, if present. As will become more apparent in the following description, the thickness of the sacrificial release layer 232 may all contribute to the dimensions of the openings which will become the staging cavity sidewalls following the formation of the stabilization layer. In an embodiment, the sacrificial release layer 232 is formed of a material which can be readily and selectively removed with vapor (e.g. vapor HF) or plasma etching. In an embodiment, the sacrificial release layer is formed of an oxide (e.g. SiO₂) or nitride (e.g. SiN_{g}), with a thickness of 0.2 μm to 2 μm. In an embodiment, the sacrificial release layer is formed using a comparatively low quality film formation technique such as sputtering, low temperature plasma enhanced chemical deposition (PECVD), or electron beam evaporation. In an embodiment, masking layer 212 is formed of a nitride (e.g. SiNₓ) and sacrificial release layer 232 is formed of an oxide (e.g. SiO₂).

Referring now to FIG. 5, in an embodiment a stabilization layer 234 is formed over the sacrificial release layer 232 and bonded to a carrier substrate 240. In accordance with embodiments of the invention, stabilization layer 234 may be formed of an adhesive bonding material. In an embodiment the adhesive bonding material is a thermosetting material such as benzocyclobutene (BCB) or epoxy.

In an embodiment, stabilization layer 234 is spin coated or spray coated over the sacrificial release layer 232, though other application techniques may be used. Following application of the stabilization layer 234, the stabilization layer may be pre-baked to remove the solvents. After pre-baking the stabilization layer 234 the handle wafer 206 is bonded to the carrier substrate 240 with the stabilization layer 234. In an embodiment, bonding includes curing the stabilization layer 234. Where the stabilization layer 234 is formed of BCB, curing temperatures should not exceed approximately 350° C., which represents the temperature at which BCB begins to degrade. Achieving a 100% full cure of the stabilization layer may not be required in accordance with embodiments of the invention. In an embodiment, stabilization layer 234 is cured to a sufficient curing percentage (e.g. 70% or greater for BCB) at which point the stabilization layer 234 will no longer reflow. Moreover, it has been observed that partially cured BCB may possess sufficient adhesion strengths with carrier substrate 240 and the sacrificial release layer 232. In an embodiment, stabilization layer may be sufficiently cured to sufficiently resist being etched during the sacrificial release layer release operation.

In an embodiment, the stabilization layer 234 is thicker than the height of nanowires 220 protruding from the base layer 208, and fills portions of the mesa trench trenches 233 and optional through holes 234. In this manner, the thickness of the stabilization layer filling mesa trenches 233 will become a portion of the staging cavity sidewalls 272 laterally adjacent the base layers 208. Any portion of the stabilization layer filling through holes 234 may additionally stabilize the nanowire devices. In the embodiment illustrated in FIG. 5, a continuous portion of stabilization layer 234 remains over the nanowires 220 so that the nanowires 220 and base layers 208 are retained within the stabilization layer 234.

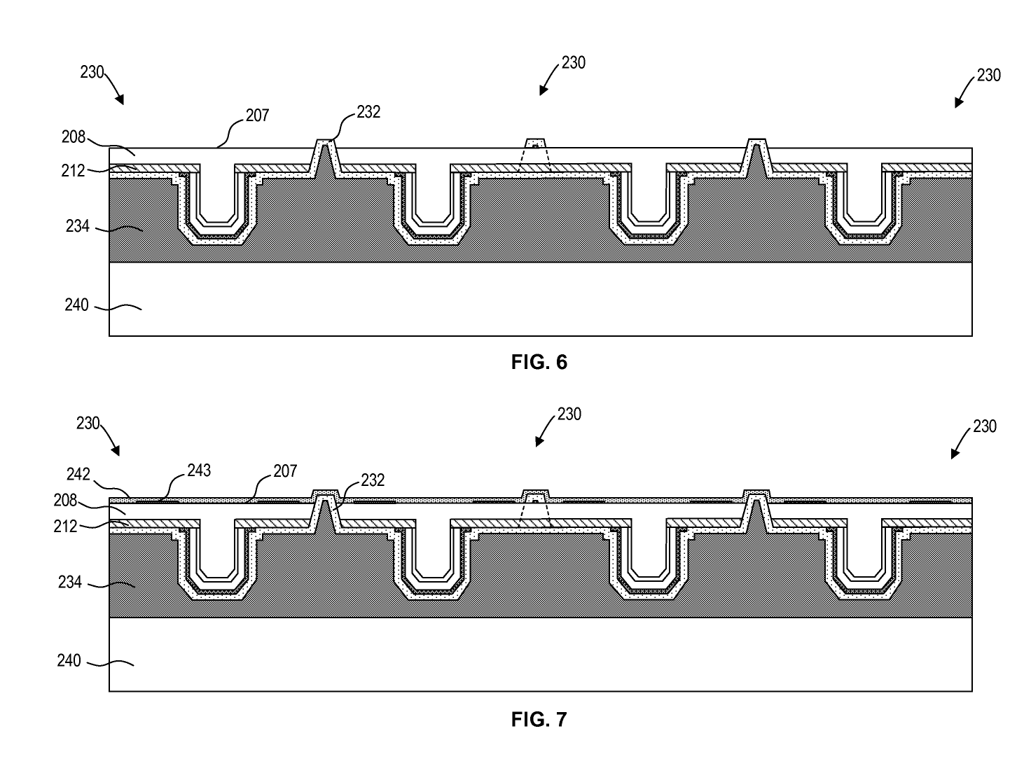

Following bonding of the handle substrate 206 to the carrier substrate 240, the handle substrate 206 is removed as illustrated in FIG. 6. Removal of handle substrate 206 may be accomplished by a variety of methods including laser lift off (LLO), grinding, and etching depending upon the material selection of the growth substrate 202, and optional etch stop layer 205 or buffer layer 204. Upon removal of the handle substrate 206, portions of the sacrificial release layer 232 may protrude above an exposed top surface of the base layer 208 for each of the mesa structures 230.

In an embodiment where the handle substrate 206 includes a growth substrate 202 formed of sapphire, removal may be accomplished using LLO in which a 202/204 interface is irradiated with an ultraviolet laser such as a Nd-YAG laser or KrF excimer laser. Absorption in the GaN buffer layer 204 at the interface with the transparent growth substrate 202 results in localized heating of the interface resulting in decomposition at the interfacial GaN to liquid Ga metal and nitrogen gas. Once the desired area has been irradiated, the transparent sapphire growth substrate 202 can be removed by remelting the Ga on a hotplate. Following removal of the growth substrate, the GaN buffer layer 204 can be removed resulting a desired thickness for base layer 208. Removal of buffer layer 204 can be performed using any of the suitable dry etching techniques described above with regard to mesa trenches 233, as well as with CMP or a combination of both.

Referring now to FIG. 7, following the removal of the handle substrate 206 a top electrode layer 242 may be formed over the top surface 207 of the base layers 208. In some embodiments, prior to forming the top electrode layer 242 an ohmic contact layer 243 can optionally be formed to make ohmic contact with the base layer 208. In an embodiment, ohmic contact layer 243 may be a metallic layer. In an embodiment, ohmic contact layer 243 is a thin GeAu layer for a GaAs or AlGaInP system. In an embodiment, ohmic contact layer 243 is a thin NiAu or NiAl layer for a GaN system. For example, the ohmic contact layer 243 may be 50 angstroms thick. In the particular embodiment illustrated, the ohmic contact layer 243 is not formed directly over the nanowires 220. For example, a metallic ohmic contact layer could potentially reduce light emission. Referring again to FIG. 15, in an embodiment the ohmic contact layers 243 form rings around, or otherwise form a grid laterally surrounding the nanowires 220.

Top electrode layer 242 may be formed of a variety of electrically conductive materials including metals, conductive oxides, and conductive polymers. In an embodiment, electrode layer 242 is formed using a suitable technique such as evaporation or sputtering. In an embodiment, electrode layer 242 is formed of a transparent electrode material. Electrode layer 242 may also be a transparent conductive oxide (TCO) such as indium-tin-oxide (ITO). Electrode layer 242 can also be a combination of one or more metal layers and a conductive oxide. In an embodiment, electrode layer 242 is approximately 600 angstroms thick ITO. In an embodiment, after forming the electrode layer 242, the substrate stack is annealed to generate an ohmic contact between the electrode layer and the top surfaces 207 of the array of mesa structures 230. Where the stabilization layer 234 is formed of BCB, the annealing temperature may be below approximately 350° C., at which point BCB degrades. In an embodiment, annealing is performed between 200° C. and 350° C., or more particularly at approximately 320° C. for approximately 10 minutes.

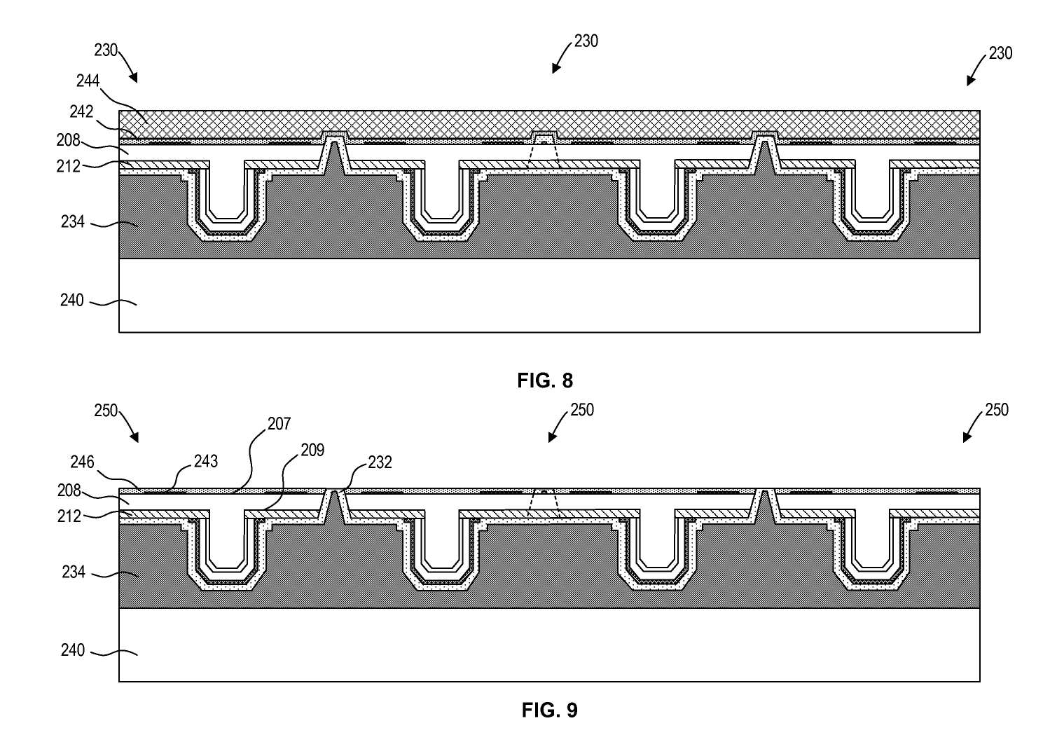

Referring now to FIG. 8, in an embodiment a patterning layer such as a photoresist is applied over the top electrode layer 242. In an embodiment, a photoresist layer 244 is spun on such that a top surface of the photoresist layer 244 fully covers raised portions of electrode layer 242 at the filled mesa trench 233 locations and optional through holes 234. Referring now to FIG. 9, in an embodiment, the photoresist layer 244 is stripped using a suitable wet solvent or plasma ashing technique until the electrode layer 242 is removed over the filled mesa trench 233 locations, exposing the sacrificial release layer 232 between the mesa structures 230, resulting in the formation of an array of top electrodes 246. Any remaining photoresist layer 244 may then be fully stripped, resulting in an array of laterally separate nanowire devices 250 embedded in a sacrificial release layer 232 and stabilization layer 234. At this point, the resultant structure still robust for handling and cleaning operations to prepare the substrate for subsequent sacrificial release layer removal and electrostatic pick up.

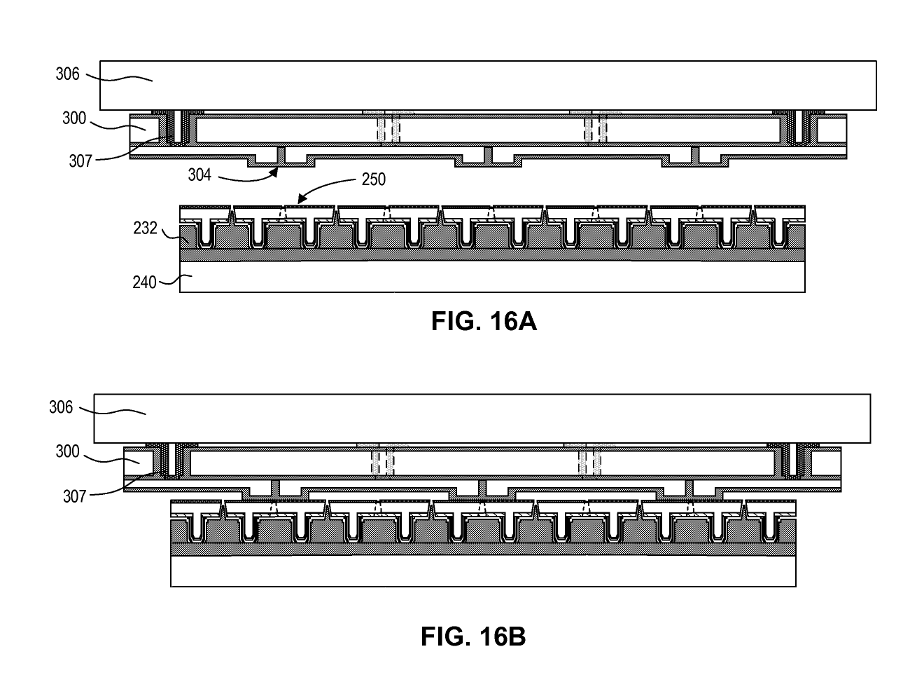

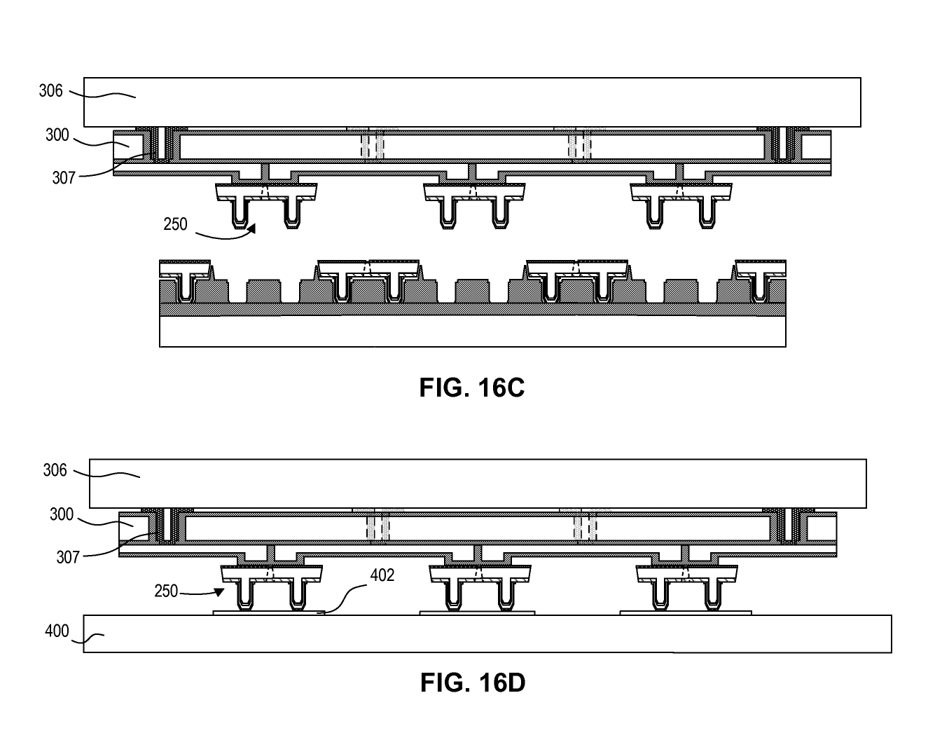

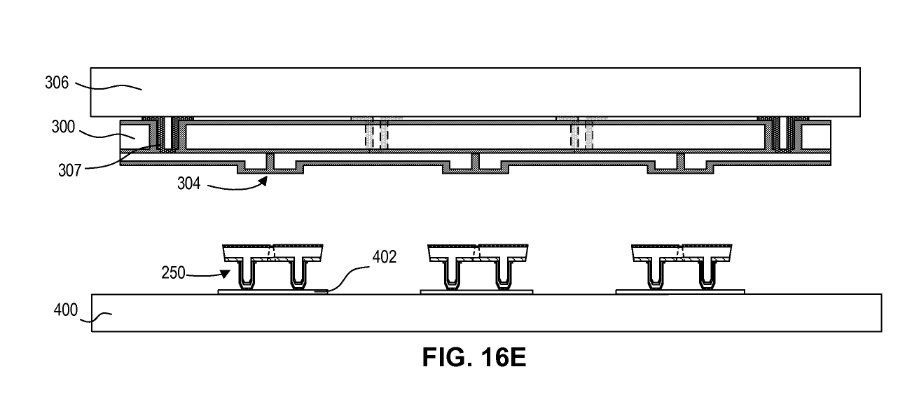

Still referring to FIG. 9, the top electrodes 246 on each nanowire device 250 cover substantially the entire top surface 207 of each base layer 208 for each nanowire device 250. As illustrated, the top electrodes 246 may not be formed over the locations of the through holes 234. In such a configuration, the top electrodes 246 cover substantially the maximum available surface area to provide a large, planar surface for contact with the electrostatic transfer head, as described in more detail in FIGS. 16A-16E. This may allow for some alignment tolerance of the electrostatic transfer head assembly.

Following the formation of discrete and laterally separate nanowire devices 250, the sacrificial release layer 232 may be removed. FIG. 10 is a cross-sectional side view illustration of an array of nanowire devices 250 within a stabilization layer after removal of the sacrificial release layer in accordance with embodiments of the invention. In the embodiments illustrated, sacrificial release layer 232 is completely removed allowing each nanowire device 250 to drop into and be retained within a staging cavity 270. A suitable etching chemistry such as HF vapor, or CF₄ or SF₆ plasma may used to etch the SiO₂ or SiNₓ sacrificial release layer 232. In an embodiment, staging cavity sidewalls 272 may further aid in keeping the array of nanowire devices 250 in place.

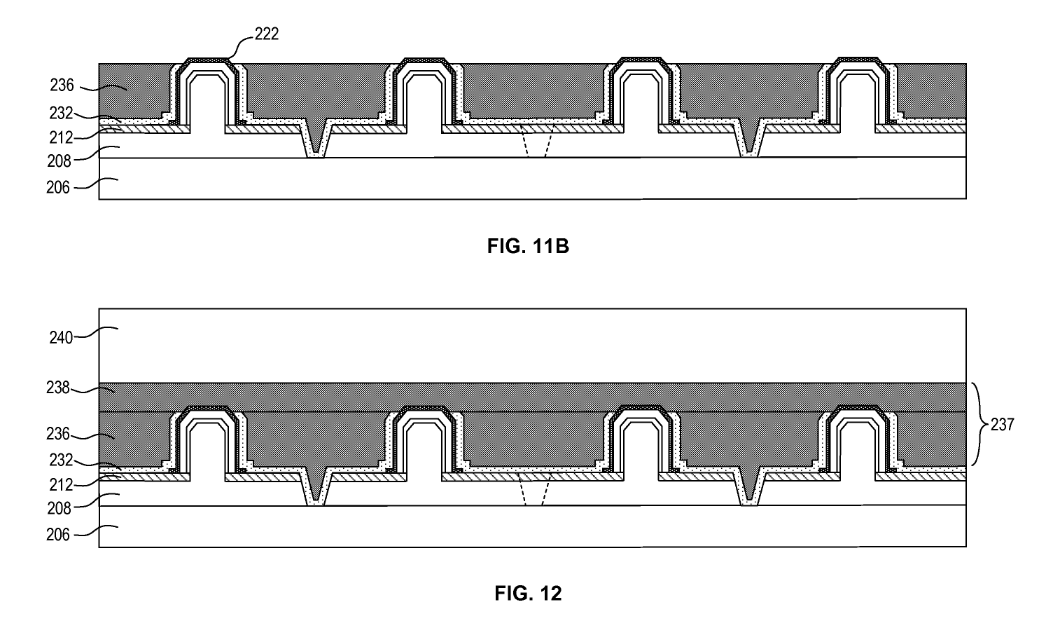

Referring now to FIGS. 11A-14, an a method of fabricating nanowire devices is described and illustrated in accordance with an embodiment of the invention, in which upon removal of the sacrificial release layer the array of nanowire devices does not fall into stabilization structures, and instead remains bonded to the stabilization layer. In such an embodiment, adhesion between the nanowire devices and the stabilization layer may be controlled by the contact area of the bottom electrode with the stabilization layer, as well as materials selection for bonding the bottom electrode and stabilization layer.

FIGS. 11A-11B are cross-sectional side view illustrations of an array of bottom electrode layers in direct contact with a stabilization layer 237 in accordance with an embodiments of the invention. Referring to FIG. 11A, in an embodiment, to form stabilization layer 237 a foundation layer 236 is coated over a sacrificial release layer 232 with a thickness reduced to expose the sacrificial release layer 232 over the nanowires 220 in accordance with an embodiment of the invention. For example, the structure illustrated in FIG. 11A may be formed by etching back stabilization layer 234 illustrated and described with regard to FIG. 5 prior to bonding to carrier substrate 240. For example, etch-back may be performed using a dry etch technique after partially curing the stabilization layer illustrated in FIG. 5. In such an embodiment, dry etching may be performed to expose the sacrificial release layer 232. After exposing the sacrificial release layer 232, the etched-back foundation layer 236 may be final cured. In an embodiment illustrated in FIG. 11B the sacrificial release layer 232 is then etched using a dry or wet etching technique to expose the bottom electrode layer 222 for each nanowire. As shown an opening is etched in the sacrificial release layer 232 spanning along a bottom-most location of the bottom electrode layer 222 for each nanowire and exposes the bottom-most portion of the bottom electrode layer 222 for each nanowire.

Following exposure of the bottom-most location of the bottom electrode layers 222, a cap layer 238 is formed over the foundation layer 236 and bonded to a carrier substrate 240. Together the foundation layer 236 and cap layer 238 form stabilization layer 237. Bonding and curing may then be performed similarly as previously described with regard to stabilization layer 234 and FIG. 5. The cap layer 238 may alternatively be applied to the carrier substrate 240 prior to bonding the handle substrate to the carrier substrate. As previously described, a thermosetting material may be used to form the stabilization layer 237 (including the foundation layer 236 and cap layer 238). For example, the thermosetting material may be associated with 10% or less volume shrinkage during curing, or more particularly about 6% or less volume shrinkage during curing so as to not delaminate from the bottom electrode layers 222. In order to increase adhesion of the cap layer 238 to the bottom electrode layers 222 and foundation layer 236, the underlying structure can be treated with an adhesion promoter such as AP3000, available from The Dow Chemical Company, in the case of a BCB stabilization layer prior to applying the cap layer 238. AP3000, for example, can be spin coated onto the underlying structure including the foundation layer 236 and the exposed bottom electrode layers 222, and soft-baked (e.g. 100° C.) or spun dry to remove the solvents prior to applying the cap layer 238.

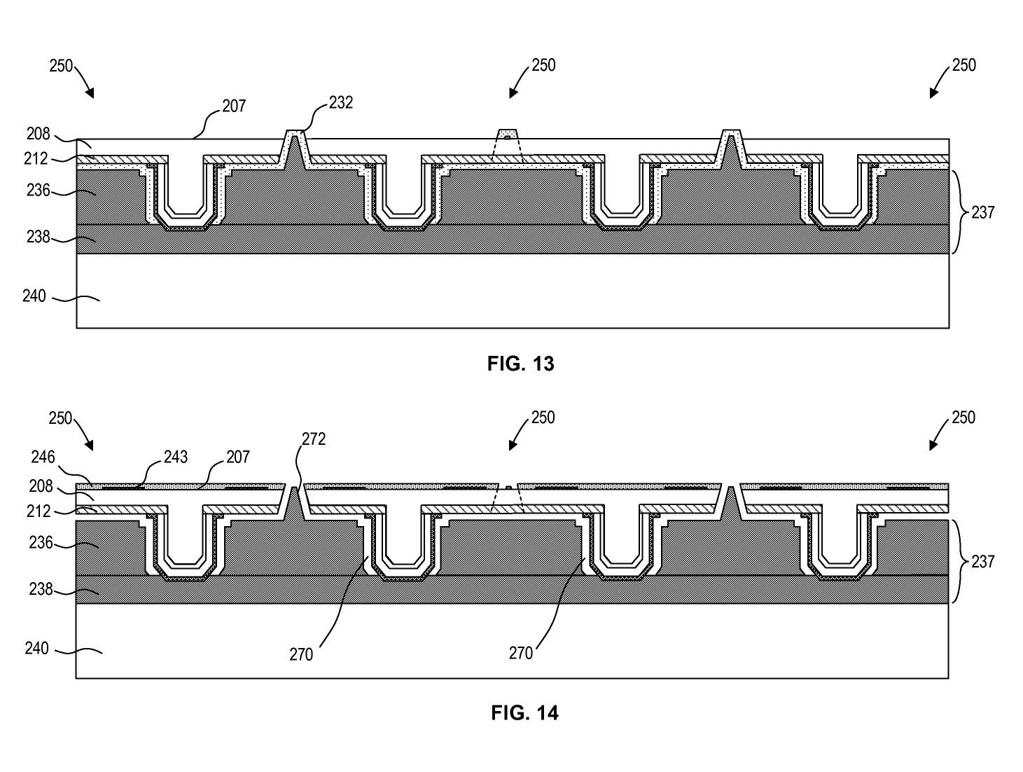

Referring now to FIGS. 13-14, the handle substrate 206 is removed, top electrodes 242 formed on the top surfaces 207 of the base layers 208, and sacrificial release layer 232 is removed similarly as described above with regard to FIGS. 6-10 to form staging cavities 270 including in an open space below each nanowire device 250. In the embodiment illustrated in FIG. 14, upon removal of the sacrificial release layer 232 the nanowire devices 250 do not drop into the array of staging cavities 270. Rather, the array of nanowire devices 250 is supported by the cap layer 238, where the array of bottom electrodes 222 contacts the cap layer 238. For example, a bonding layer such gold in a bottom electrode 222 layer stack may be in direct contact with the cap layer 238. In this manner, the surface area and profile of the surface area where the bottom electrodes 222 are in contact with the cap layer 238 is partly responsible for retaining the nanowire devices 250 in place within the stabilization layer, and also contributes the adhesion forces that must be overcome in order to pick up the nanowire devices 250 from the carrier substrate. Thus, referring back to FIG. 11B, the amount of etch-back used to form the foundation layer 236 and amount of sacrificial release layer 232 initially removed prior to bonding to the carrier substrate may determine the resulting adhesion to the stabilization layer on the carrier substrate. Accordingly, increased adhesion may be obtained by further etch-back that further exposes the bottom electrodes 222 along the length of the nanowires 220. Staging cavity sidewalls 272 may additionally aid in keeping the array of nanowire devices 250 in place should an adhesive bond be broken between any of the nanowire devices 250 and the cap layer 238.

FIG. 15 is a schematic top view illustration of an array of nanowire devices 250 carried on a carrier substrate 240, with each nanowire device including one or more through holes in accordance with an embodiment of the invention. In the exemplary embodiment illustrated, each nanowire device includes a plurality of nanowires 220 on the base layer 208 and one or more through holes 234 formed through the base layer 208. Each nanowire device 250 is laterally separate from adjacent nanowire devices by mesa trenches 233. As described above, one or more through holes 234 may be formed through each base layer 208 to aid in removing the sacrificial release layer. In an embodiment, the stabilization layer occupying space in the mesa trenches 233 becomes a portion of the staging cavity sidewalls 272 laterally adjacent the base layers 208. A portion of the stabilization layer may also occupy space within the through holes 234.

FIGS. 16A-16E are cross-sectional side view illustrations of an array of electrostatic transfer heads 304 transferring nanowire devices 250, which may be nanowire LED devices, from carrier substrate 240 to a receiving substrate 300 in accordance with an embodiment of the invention. FIG. 16A is a cross-sectional side view illustration of an array of micro device transfer heads 304 supported by substrate 300 and positioned over an array of nanowire devices 250 stabilized on carrier substrate 240. The array of nanowire devices 250 is then contacted with the array of transfer heads 304 as illustrated in FIG. 16B. As illustrated, the pitch of the array of transfer heads 304 is an integer multiple of the pitch of the array of nanowire devices 250. A voltage is applied to the array of transfer heads 304. The voltage may be applied from the working circuitry within a transfer head assembly 306 in electrical connection with the array of transfer heads through vias 307. The array of nanowire devices 250 is then picked up with the array of transfer heads 304 as illustrated in FIG. 16C. The array of nanowire devices 250 is then placed in contact with contact pads 402 (e.g. gold, indium, tin, etc.) on a receiving substrate 400, as illustrated in FIG. 16D. The array of nanowire devices 250 is then released onto contact pads 402 on receiving substrate 400 as illustrated in FIG. 16E. For example, the receiving substrate may be, but is not limited to, a display substrate, a lighting substrate, a substrate with functional devices such as transistors or ICs, or a substrate with metal redistribution lines.

In accordance with embodiments of the invention, heat may be applied to the carrier substrate, transfer head assembly, or receiving substrate during the pickup, transfer, and bonding operations. For example, heat can be applied through the transfer head assembly during the pick up and transfer operations, in which the heat may or may not liquefy nanowire device bonding layers. The transfer head assembly may additionally apply heat during the bonding operation on the receiving substrate that may or may not liquefy one of the bonding layers on the nanowire device or receiving substrate to cause diffusion between the bonding layers.

The operation of applying the voltage to create a grip pressure on the array of nanowire devices can be performed in various orders. For example, the voltage can be applied prior to contacting the array of nanowire devices with the array of transfer heads, while contacting the nanowire devices with the array of transfer heads, or after contacting the nanowire devices with the array of transfer heads. The voltage may also be applied prior to, while, or after applying heat to the bonding layers.

Where the transfer heads 304 include bipolar electrodes, an alternating voltage may be applied across a the pair of electrodes in each transfer head 304 so that at a particular point in time when a negative voltage is applied to one electrode, a positive voltage is applied to the other electrode in the pair, and vice versa to create the pickup pressure. Releasing the array of nanowire devices from the transfer heads 304 may be accomplished with a varied of methods including turning off the voltage sources, lower the voltage across the pair of electrodes, changing a waveform of the AC voltage, and grounding the voltage sources.

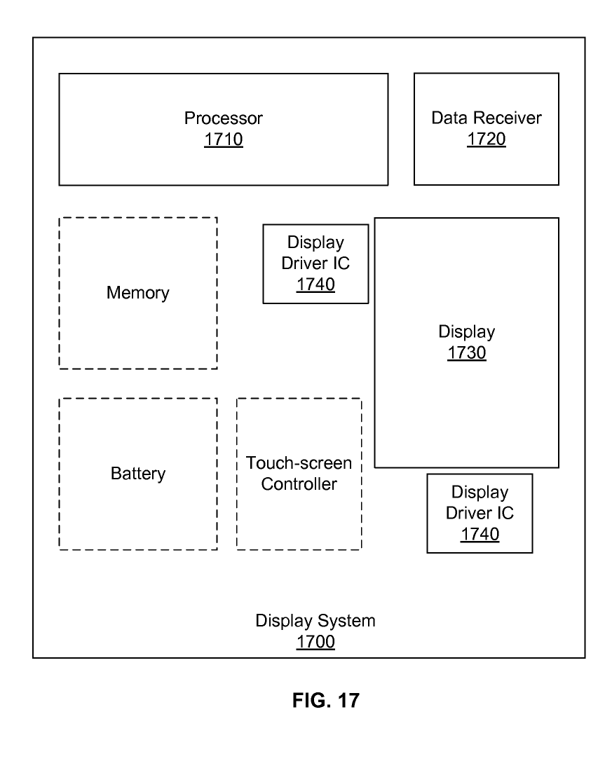

FIG. 17 illustrates a display system 1700 in accordance with an embodiment. The display system houses a processor 1710, data receiver 1720, a display 1730, and one or more display driver ICs 1740, which may be scan driver ICs and data driver ICs. The data receiver 1720 may be configured to receive data wirelessly or wired. Wireless may be implemented in any of a number of wireless standards or protocols including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The one or more display driver ICs 1740 may be physically and electrically coupled to the display 1730.

In some embodiments, the display 1730 includes one or more nanowire devices 250 that are formed in accordance with embodiments of the invention described above. Depending on its applications, the display system 1700 may include other components. These other components include, but are not limited to, memory, a touch-screen controller, and a battery. In various implementations, the display system 1700 may be a television, tablet, phone, laptop, computer monitor, kiosk, digital camera, handheld game console, media display, ebook display, or large area signage display.

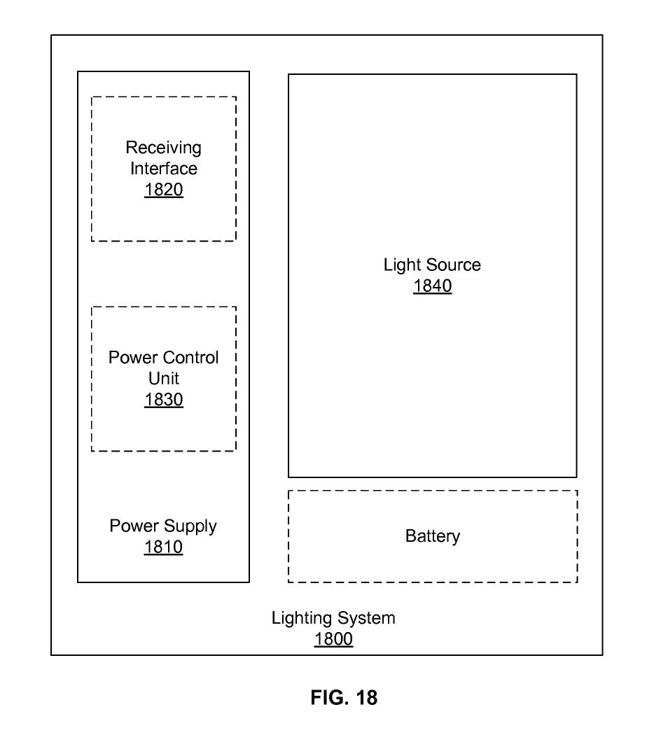

FIG. 18 illustrates a lighting system 1800 in accordance with an embodiment. The lighting system houses a power supply 1810, which may include a receiving interface 1820 for receiving power, and a power control unit 1830 for controlling power to be supplied to the light source 1840. Power may be supplied from outside the lighting system 1800 or from a battery optionally included in the lighting system 1800. In some embodiments, the light source 1840 includes one or more nanowire devices 250 that are formed in accordance with embodiments of the invention described above. In various implementations, the lighting system 1800 may be interior or exterior lighting applications, such as billboard lighting, building lighting, street lighting, light bulbs, and lamps.

In utilizing the various aspects of this invention, it would become apparent to one skilled in the art that combinations or variations of the above embodiments are possible for fabricating and transferring nanowire devices. Although the present invention has been described in language specific to structural features and/or methodological acts, it is to be understood that the invention defined in the appended claims is not necessarily limited to the specific features or acts described. The specific features and acts disclosed are instead to be understood as particularly graceful implementations of the claimed invention useful for illustrating the present invention.

What is claimed is:

1. A nanowire device comprising:
a base layer;
a nanowire on and protruding away from a first surface of the base layer; wherein the nanowire comprises a core, a shell, and an active layer between the core and the shell;
a top electrode layer on a second surface of the base layer opposite the first surface and in electrical contact with the core; and
a bottom electrode layer on and in electrical contact with the shell.

2. The nanowire device of claim 1, wherein the top electrode layer is formed of a transparent or semi-transparent material.

3. The nanowire device of claim 2, wherein the top electrode layer covers substantially all the second surface of the base layer.

4. The nanowire device of claim 3, wherein the bottom electrode includes a layer stack.

5. The nanowire device of claim 4, wherein the bottom electrode includes a mirror layer.

6. The nanowire device of claim 4, wherein the bottom electrode includes a bonding layer formed of a noble metal.

7. The nanowire device of claim 3, comprising:
a plurality of nanowires on and protruding away from the first surface of the base layer;
wherein each nanowire comprises a core, a shell, and an active layer between the core and the shell;
wherein the top electrode layer is on the second surface of the base layer opposite the first surface and in electrical contact with the core of each nanowire; and
one or more bottom electrode layers on and in electrical contact with the shells of the plurality of nanowires.

8. The nanowire device of claim 7, comprising a corresponding plurality of bottom electrode layers on and in electrical contact with the shells of the plurality of nanowires.

9. The nanowire device of claim 7, further comprising a patterned mask layer on the base layer, wherein the cores of the plurality of nanowires extend through corresponding openings in the patterned mask layer.

10. The nanowire device of claim 9, further comprising a through-hole through an entire thickness of the base layer and the mask layer located laterally between two nanowires.

11. A structure comprising:
a carrier substrate,
a stabilization layer on the carrier substrate, the stabilization layer including an array of staging cavities;
an array of nanowire devices within the array of staging cavities:
wherein each nanowire device comprises:
a base layer characterized by a maximum width of the micro scale; and
a nanowire on and protruding away from the base layer, the nanowire characterized by a maximum width of the nano scale.

12. The structure of claim 11, further comprising a sacrificial release layer spanning between the stabilization layer and the array of nanowire devices.

13. The structure of claim 12, wherein the array of nanowire devices are embedded in the sacrificial release layer.

14. The nanowire device of claim 11, wherein the stabilization layer comprises a thermoset material.

15. The nanowire device of claim 11, wherein each nanowire comprises a core, a shell, and an active layer between the core and the shell.

16. The nanowire device of claim 15, further comprising a bottom electrode layer on and in electrical contact with the shell for each nanowire.

17. The nanowire device of claim 16, wherein the sacrificial release layer spans along a bottom-most location of the bottom electrode layer for each nanowire.

18. The nanowire device of claim 17, wherein the sacrificial release layer includes an array of openings such that the sacrificial release layer does not span along a bottom-most location of the bottom electrode layer for each nanowire.

19. The nanowire device of claim 18, wherein the bottom electrode layer for each nanowire is in direct contact with the stabilization layer.

20. A method of forming a nanostructure comprising:
depositing a bottom electrode layer on a nanowire, wherein the nanowire protrudes from a base layer formed on a handle substrate, and the nanowire comprises a core, a shell, and an active layer between the core and the shell;
etching a mesa trench through the base layer, wherein the mesa trench laterally surrounds the nanowire;
depositing a sacrificial release layer over the base layer and nanowire, and within the mesa trench;
bonding the handle substrate to a carrier substrate with a stabilization layer, wherein the nanowire is retained within the stabilization layer; and
removing the handle substrate.

21. The method of claim 20, wherein bonding the handle substrate to the carrier substrate with the stabilization layer comprises:
coating a thermosetting material over the sacrificial release layer; and
curing the thermosetting material.

22. The method of claim 20, wherein bonding the handle substrate to the carrier substrate with the stabilization layer comprises:
coating a foundation layer over the sacrificial release layer;
reducing a thickness of the foundation layer;
removing a portion of the sacrificial release layer to expose a portion of the bottom electrode layer over the nanowire; and
coating a cap layer over the foundation layer.

23. A method comprising:
picking up an array of nanowire devices from a carrier substrate with an electrostatic transfer head assembly supporting an array of electrostatic transfer heads;
contacting a receiving substrate with the array of nanowire devices;
bonding the array of nanowire devices to the receiving substrate; and
releasing the array nanowire devices onto the receiving substrate.

24. The method of claim 23, wherein each nanowire device comprises:
a base layer;
a nanowire on and protruding away from a first surface of the base layer; wherein the nanowire comprises a core, a shell, and an active layer between the core and the shell;
a top electrode layer on a second surface of the base layer opposite the first surface and in electrical contact with the core; and
a bottom electrode layer on and in electrical contact with the shell.

25. The method of claim 23, wherein each nanowire device comprises:
a base layer characterized by a maximum width of the micro scale; and
a nanowire on and protruding away from the base layer, the nanowire characterized maximum width of the nano scale.

26. The method of claim 23, wherein picking up the array of nanowire devices from the carrier substrate with the electrostatic transfer head assembly supporting the array of electrostatic transfer heads comprises:
contacting the top electrode layer of each nanowire device with a corresponding electrostatic transfer head.

27. The method of claim 23, further comprising removing a sacrificial release layer between the array of nanowire devices and the carrier substrate prior to picking up the array of nanowire devices.
